(19) United States
(12) Patent Application Publication
(10) Pub. No.: US 2008/0197476 A1
(43) Pub. Date: Aug. 21, 2008

(54) SEMICONDUCTOR DEVICE

(75) Inventor: Kenji Sunaga, Gunma (JP)

Correspondence Address: MORRISON & FOERSTER LLP, 1650 TYSONS BOULEVARD, SUITE 400, MCLEAN, VA, 22102, US

(73) Assignees: SANYO ELECTRIC CO., LTD., Moriguchi-shi (JP); SANYO SEMICONDUCTOR CO., LTD., Ora-gun (JP)

(21) Appl. No.: 12/035,208

(22) Filed: Feb. 21, 2008

(30) Foreign Application Priority Data
Feb. 21, 2007 (JP) 2007-041263

(51) Int. Cl. H01L 23/48

(52) U.S. Cl. 257/690; 257/E23.01

(57) ABSTRACT

The bump diameter of a bump electrode is reduced. An external connection substrate is bonded to a semiconductor chip, and is provided with, at an edge portion thereof, an external connection electrode protruding from the semiconductor chip, and continuing on both principal surfaces of the external connection substrate. The external connection electrode on a principal surface side of the external connection substrate is connected to the bump electrode through an opening in a resin layer covering the external connection electrode. The external connection electrode on the other principal surface is connected to a conductive path of a mounting board. The chip and the external connection substrate are fixed together by an underfill material. The external connection electrode and the conductive path are fixed together by solder. The bonding strength can be improved even with a reduced bump diameter so that the chip can be reduced in size.

### BACKGROUND OF THE INVENTION

This application claims priority from Japanese Patent Application Number JP2007-041263 filed on Feb. 21, 2007, the content of which is incorporated herein by reference in its entirety.

1. Field of the Invention

The present invention relates to a semiconductor device, and more particularly relates to a semiconductor device with a higher reliability achieved by preventing a poor electrode connection due to a reduction in the size of a chip.

2. Description of the Related Art

In order to achieve a smaller and thinner semiconductor device, a flip-chip mounting technique is employed. In this technique, a bump electrode is provided on one principal surface side of a semiconductor chip, and is connected to a conductive pattern or the like on the mounting board side.

With reference to FIGS. 9A and 9B, a conventional flip-chip mountable semiconductor device will be described by taking, as an example, a semiconductor chip 50 in which a MOSFET is formed. FIG. 9A is a plan view of the semiconductor chip 50. FIG. 9B is a schematic diagram showing a side view of the semiconductor chip 50 in FIG. 9A. Here, the semiconductor chip 50 is flip-chip mounted on a mounting board.

While a detailed illustration of an element region is omitted, an element region 52, including a channel region and a source region, is provided, as indicated by the broken line, in a semiconductor substrate 51 functioning as a drain region. A gate electrode (unillustrated) made of a conductive material such as polysilicon is also provided to the semiconductor substrate 51. In addition, a source electrode, a drain electrode, and a gate pad electrode, all of which are not illustrated, are provided on a surface of the semiconductor substrate 51 by sputtering a metal, for example, aluminum (Al). The source electrode, the drain electrode, and the gate pad electrode are connected respectively to a source region, a drain region, and the gate electrode.

A source bump electrode 111 is in contact with the source electrode. A gate bump electrode 112 and a drain bump electrode 113 are connected to the unillustrated gate pad electrode and a drain electrode 114, respectively.

As described above, the bump electrodes connected to the element region are provided on the surface of substrate so that this chip can be flip-chip mounted.

The mounting board is, for example, a printed board 55. A conductive path 56 having a desired pattern is provided on a surface of the printed board 55. The bump electrodes 111, 112, and 113 are fixed to the conductive path 56, so that the semiconductor chip 50 is mounted on the printed board 55. This technology is described for instance in Japanese Patent Application Publication No. 2002-368218.

In the above structure employing a bump electrode, a large bump (ball) diameter is generally secured in order to facilitate the mounting, and concurrently to obtain a sufficient reliability.

However, there is a problem that, as chip shrink progresses, the footprint of the bump electrode on a chip becomes larger. For example, an element region where a transistor cell is disposed can be shrunk by the progress of finer processes, thereby contributing to a reduction in chip size. However, it is necessary that multiple bump electrodes provided on a chip be spaced from one another at predetermined intervals. For this reason, when the bump diameter is, for example, approximately 300 μm, the chip size is limited. As a result, a problem arises that further reduction in size of the chip cannot be achieved.

Meanwhile, when the bump diameter of the bump electrode is reduced, it is impossible to secure a sufficient contact area with the mounting board (for example, a printed board) on which a chip is flip-chip mounted. For this reason, a bonded portion (a portion where the semiconductor chip 50 and each of the bump electrodes 111 to 113 are bonded together, or a portion where each of the bump electrodes 111 to 113 and the printed board 55 are bonded together) easily peels off due to a shock from outside, for example, in a case where a mobile terminal is dropped. As a result, there is a problem that a poor contact occurs.

Moreover, even if the required element region can be shrunk, it is necessary to secure a large chip size for the bump electrodes. This leads to a reduction in wafer yield. In other words, in addition to the problem in the characteristics, there has been a problem that cost reduction is difficult to achieve.

### SUMMARY OF THE INVENTION

The invention provides a semiconductor device that includes a semiconductor chip comprising a device element formed therein and a bump electrode disposed on a surface of the semiconductor chip, an external connection substrate adhered to the surface of the semiconductor chip by an insulating adhesive, a lateral size of the external connection substrate being larger than a lateral size of the semiconductor chip so that an edge portion of the external connection substrate is not covered by the semiconductor chip, an external connection electrode disposed on the external connection substrate so as to cover the edge portion of external connection substrate and connected to the bump electrode.

### BRIEF DESCRIPTION OF THE DRAWINGS

FIGS. 1A, 1B, 1C and 1D are a plan view, a cross-sectional view, a plan view and a plan view, respectively, for explaining a semiconductor device of a first embodiment of the present invention.

FIGS. 2A to 2E are plan views for explaining the semiconductor device of the first embodiment of the present invention.

FIG. 3 is a cross-sectional view for explaining the semiconductor device of the first embodiment of the present invention.

FIGS. 4A and 4B are plan views for explaining the semiconductor device of the first embodiment of the present invention.

FIGS. 5A and 5B are plan views for explaining the semiconductor device of the first embodiment of the present invention.

FIGS. 6A and 6B are a plan view and a cross-sectional view, respectively, for explaining the semiconductor device of the first embodiment of the present invention.

FIGS. 7A and 7B are an equivalent circuit diagram and a schematic circuit diagram, respectively, for explaining the semiconductor device of the first embodiment of the present invention.

FIG. 8 is a cross-sectional view for explaining a semiconductor device of a second embodiment of the present invention.

FIGS. 9A and 9B show a conventional semiconductor device.

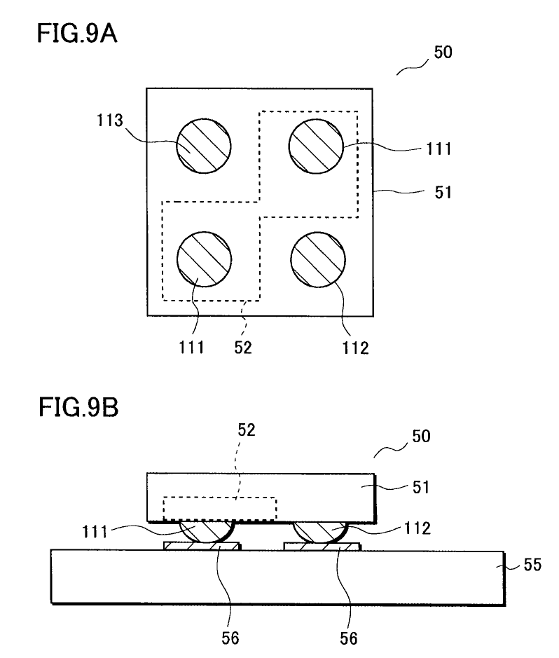

### DETAILED DESCRIPTION OF THE PREFERRED EMBODIMENTS

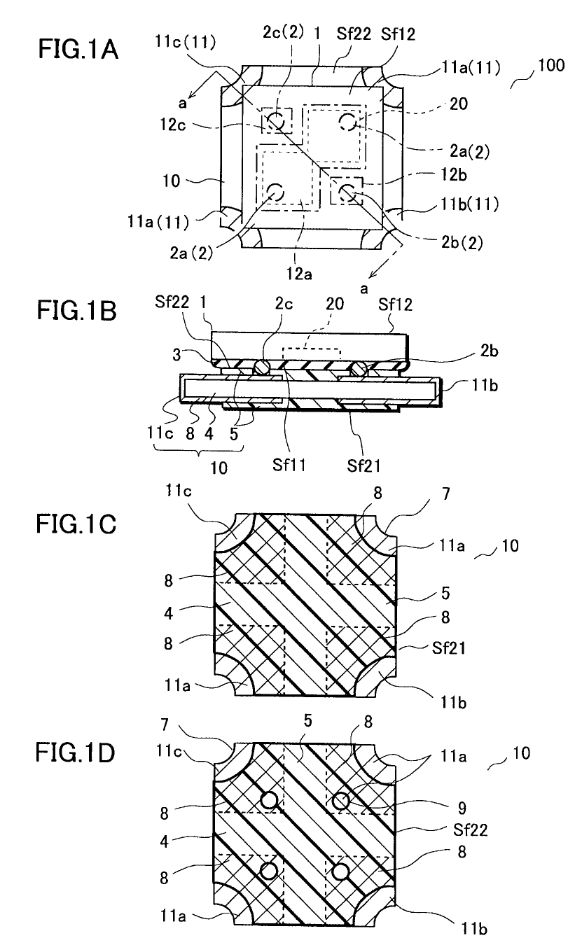

Embodiments of the present invention will be described in detail below with reference to FIGS. 1A to 1D, 2A to 2E, 3, 4A and 4B, 5A and 5B, 6A and 6B, 7A and 7B, as well as, 8.

First of all, a first embodiment of the present invention will be described with reference to FIGS. 1A to 1D, 2A to 2E, 3, 4A and 4B, 5A and 5B, 6A and 6B, as well as, 7A and 7B.

FIGS. 1A, 1B, 1C and 1D show a semiconductor device of the first embodiment. FIG. 1A is a plan view showing the semiconductor device. FIG. 1B is a cross-sectional view taken along the line a-a in FIG. 1A. FIG. 1C is a plan view showing a first principal surface side of an external connection substrate. FIG. 1D is a plan view showing a second principal surface side of the external connection substrate.

A semiconductor device 100 of these embodiments includes: a semiconductor chip 1, bump electrodes 2 (2a to 2c), and an external connection substrate 10. The external connection substrate 10 is bonded, with an insulating adhesive 3, to the first principal surface side of the semiconductor chip 1. Note that, in FIG. 1A, the bump electrodes 2, and an electrode wiring layer for an element region are indicated by alternate long and short dashed lines, and the insulating adhesive 3 is not shown.

Refer to FIG. 1A. In the semiconductor chip 1, an element region 20 of, for example, an insulated gate semiconductor element having a single function (of a discrete type) is formed. The element region 20 is formed by providing a desired impurity region in a semiconductor substrate. Although a MOSFET (Metal Oxide Semiconductor Field Effect Transistor) is described here as an example, an IGBT (Insulated Gate Bipolar Transistor) may be employed. Moreover, a junction FET, a bipolar transistor, a diode, a thyristor or the like may alternatively be employed instead of the insulated gate semiconductor element.

The element region 20 is provided in the semiconductor substrate as indicated by the broken line, while a detailed illustration thereof is omitted. The semiconductor substrate has a first principal surface Sf11 and a second principal surface Sf12, and serves as a drain region. The element region 20 is provided by forming, in the first principal surface Sf11 of the semiconductor substrate, impurity regions such as a channel region and a source region, as well as a gate electrode of a conductive material such as polysilicon. Moreover, on the first principal surface Sf11, wiring electrode layers 12 are provided by sputtering a metal such as aluminum (Al). The wiring electrode layers 12 include a source electrode 12a, a drain electrode 12b and a gate pad electrode 12c, which are connected to the source region, the drain region and the gate electrode, respectively.

On the second principal surface Sf12 of the semiconductor chip 1, the semiconductor substrate is exposed, or a metal film is provided as needed.

Additionally, on the first principal surface Sf11 side of the semiconductor chip 1, provided are the bump electrodes 2 connected respectively to the source electrode 12a, the drain electrode 12b, and the gate pad electrode 12c. The bump electrodes 2 include source bump electrodes 2a, a drain bump electrode 2b and a gate bump electrode 2c, which correspond to the source electrode 12a, the drain electrode 12b and the gate pad electrode 12c, respectively. At least four bump electrodes 2 are provided. Each bump electrode 2 is formed of gold (Au), copper (Cu), gold-tin (Au-Sn), or solder. The bump diameter of each bump electrode 2 is from 50 μm to 150 μm (as an example, 80μm in the case of an Au bump).

On the first principal surface Sf11 side of the semiconductor chip 1, the external connection substrate 10 is provided. The external connection substrate 10 includes an insulating film 4 and external connection electrodes 11 (11a, 11b, and 11c). The external connection substrate 10 is obtained by covering, with resin layers 5, both the principal surfaces of the insulating film 4 provided with the external connection electrodes 11 respectively at the edge portions of the insulating film 4. The insulating film 4 is made of, for example, polyimide, and the thickness of the insulating film 4 is, for example, from 0.01 mm to 0.15 mm. Each resin layer 5 is, for example, a solder resist.

The external connection substrate 10 is a little larger than the semiconductor chip 1, and is provided to be exposed from the periphery of the semiconductor chip 1 when viewed in the plan view, as shown in FIG. 1A. When the semiconductor device 100 in this embodiment is mounted, solder is used, which will be described later.

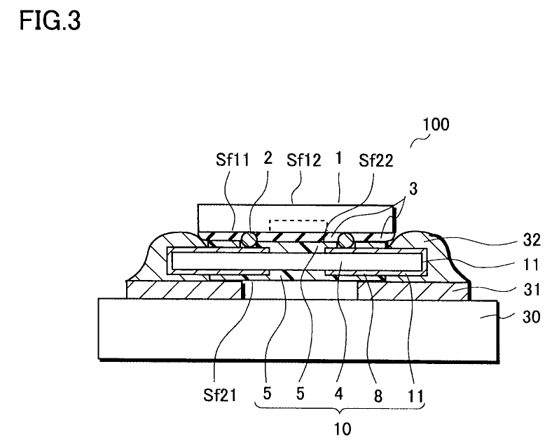

The edge of the external connection substrate 10 extends from the edge of the semiconductor chip 1, as shown in FIG. 1B. The length of this extension is about 0.05 mm to 0.3 mm. Such a configuration allows observation of the solder during the mounting, as shown in FIG. 3. In FIG. 3, the solder 32 extends from a first principal surface Sf21 side of the external connection substrate 10 to its second principal surface Sf22 side along a side surface of the external connection substrate 10.

Now refer to FIGS. 1B to 1D. At each of the edge portions (for example, the corner portions) of the insulating film 4, the corresponding one of the external connection electrodes 11 (11a to 11c) covers continuously, the first principal surface Sf21 side, the side of the edge portion, and the second principal surface Sf22 side, of the insulating film 4. Each external connection electrode 11 is a part of a metal layer 8 provided at the corresponding one of the corner portions of the insulating film 4 by plating, evaporation, or the like.

The resin layers 5, covering the principal surfaces of the insulating film 4, also cover a part of each metal layer 8. Moreover, the resin layers 5 are not provided at the corner portions of the semiconductor chip 1. There is also a region where a part of each metal layer 8 is exposed. Here, the part, exposed from the resin layer 5, of each metal layer 8 is called the external connection electrode 11. The insulating film 4 is larger than the semiconductor chip 1 as described above.

At the corner portions of insulating film 4, the resin layers 5 are patterned along the shape of the insulating film 4 so as to be smaller than (on the inner side of) the insulating film 4, as shown in FIGS. 1C and 1D. As a result, at the edge portions of the insulating film 4 protruding from the semiconductor chip 1, the external connection electrodes 11 are exposed to the outside.

FIG. 1C is a plan view showing the first principal surface Sf21 side of the external connection substrate 10, to which side the mounting board (unillustrated here) is to be connected.

The insulating film 4 in this embodiment is provided with cutouts 7, each having a fan shape (or in a semicircle shape), respectively at the edge portions (for example, the corner portions) of the insulating film 4. The external connection electrodes 11 are provided to cover the respective cutouts 7.

The provision of the cutouts 7 allows the solder to easily flow along the concave shapes of the cutouts 7, thus further improving the adhesion of the solder.

The resin layer 5 is patterned on the first principal surface Sf21 side so that the external connection electrodes 11 are exposed, each in a band shape along the pattern of the corresponding cutout 7, at the edge portions (the corner portion) of the insulating film 4.

FIG. 1D is a plan view showing the second principal surface Sf22 side of the external connection substrate 10, to which side the semiconductor chip 1 is to be connected. In the same manner as the first principal surface Sf21 side, the resin layer 5 is patterned on the second principal surface Sf22 side so that the external connection electrodes 11 are exposed, each in a band shape along the pattern of the corresponding cutout 7, at the edge portions (the corner portion) of the insulating film 4.

In addition, openings 9 are formed in the resin layer 5 on the second principal surface Sf22 side, at positions corresponding respectively to the bump electrodes 2 of the semiconductor chip 1. Parts of the metal layers 8 are thus exposed from these openings 9 to also serve as parts of the corresponding external connection electrodes 11. Accordingly, the bump electrodes 2 are connected respectively to the external connection electrodes 11 exposed from the openings 9 on the second principal surface Sf22 side (see FIG. 1A).

Using the solder resist for each resin layer 5 makes it possible to maintain the shape of solder bumps, and to self-align the solder bumps, when solder is used for the bump electrodes 2.

The insulating adhesive 3 is made of, for example, an underfill material. The underfill material is, for example, polyimide containing an adhesive material. The underfill material is filled between the semiconductor chip 1 and the external connection substrate 10 to uniformly bond the semiconductor chip 1 and the external connection substrate 10 together.

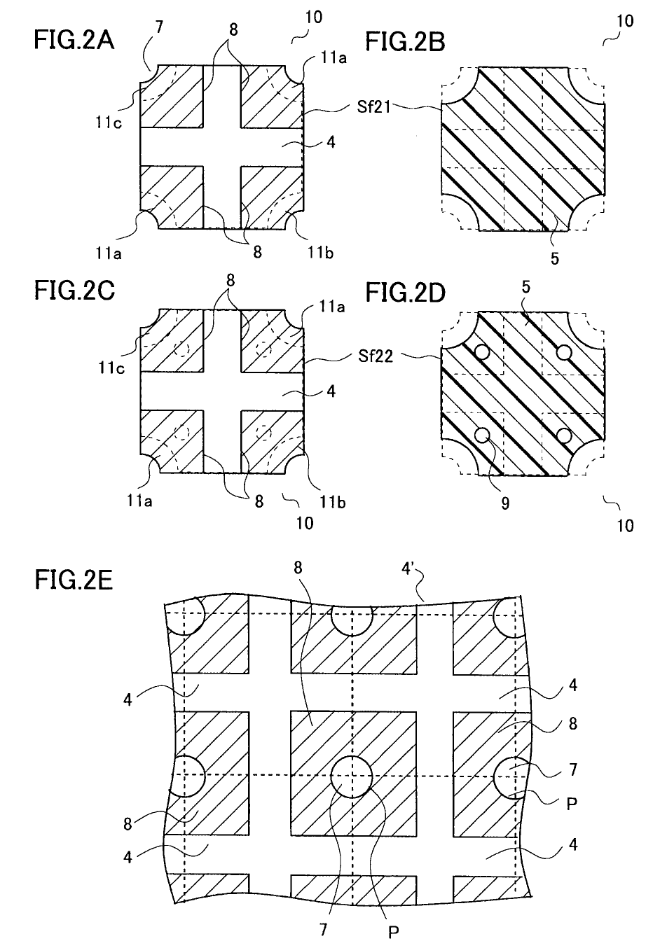

The metal layers 8 and the resin layers 5 provided on the insulating film 4 are further described with reference to FIGS. 2A to 2E. FIG. 2A is a plan view showing the pattern of the metal layers 8 on the first principal surface Sf21 side of the external connection substrate 10. FIG. 2B is a plan view showing the pattern of the resin layer 5 on the first principal surface Sf21 side. FIG. 2C is a plan view showing the pattern of the metal layers 8 on the second principal surface Sf22 side. FIG. 2D is a plan view showing the pattern of the resin layer 5 on the second principal surface Sf22 side. Note that, in each of FIGS. 2A and 2C, the pattern of the resin layer 5 is indicated by the broken line, whereas in each of FIGS. 2B and 2D, the metal layers 8 are indicated by the broken line. In addition, FIG. 2E illustrates a method of forming the insulating film 4.

As shown in FIGS. 2A and 2C, on the first principal surface Sf21 and the second principal surface Sf22, the metal layers 8 are disposed respectively at the edge portions (for example, the corner portions) of the insulating film 4, to be spaced from each other.

Refer to FIG. 2E. The insulating film 4 is formed as follows. Firstly, a large-sized film 4′ is provided with multiple through holes P. The metal layers 8 are formed by plating, with a metal, the peripheries and the insides (the sidewalls) of the through holes P in a manner that the metal layers 8 are spaced from one another. Thereafter, the large-sized film 4′ is cut into pieces, each to be used as the insulating film 4, along the lines each passing through the centers of the through holes P.

As a result, the insulating film 4 is provided with the cutouts 7, each in a fan shape (or in a semicircle shape), at the respective edge portions (for example, the corner portions) of the insulating film 4. In addition, each metal layer 8 continuously covers both the principal surfaces of the corresponding corner portion of the insulating film 4. In other words, the metal layer 8 on the first principal surface Sf21 and the metal layer 8 on the second principal surface Sf22 are connected to each other by the metal layer 8 covering the side of the cutout 7 at the corresponding edge portion (see FIG. 1B).

Additionally, since the resin layer 5 covering the metal layers 8 is patterned as indicated by the broken line, the external connection electrodes 11 are exposed to the outside at the respective edge portions.

Each source bump electrode 2a, the drain bump electrode 2b, and the gate bump electrode 2c are connected, respectively, to the external connection electrodes 11a, 11b, and 11c, which are exposed to the outside from the openings 9 on the second principal surface Sf22 of the external connection substrate 10. Each source bump electrode 2a, the drain bump electrode 2b, and the gate bump electrode 2c are thus extended to the first principal surface Sf21 side by the external connection electrodes 11 at the edge portions, thereby being connected to the conductive path of the mounting board.

As described above, the metal layers 8 are provided to correspond to the bump electrodes 2, and connect the bump electrodes 2 to the conductive path of the mounting board.

Although the case of disposing the metal layers 8 at the corner portions is taken as an example in this embodiment, the metal layer 8 may be disposed at each side of the external connection substrate 10 in accordance with the disposition of the bump electrodes 2 or the disposition of the conductive path of the mounting board. Moreover, although the metal layers 8 on both the principal surfaces are shown by the same pattern in this embodiment, a preferable pattern is selected for the metal layer 8 on the second principal surface Sf22 side in accordance with the number of, or the disposition of, the bump electrodes 2 of the semiconductor chip 1 (This selection will be described later).

As shown in FIGS. 2B and 2D, the resin layers 5 are formed in different patterns from each other, respectively on the first principal surface Sf21 and the second principal surface Sf22. These resin layers 5 are the same in that the external connection electrodes 11 are patterned to be exposed, each in a band shape along the corresponding cutout 7, at the corner portions. However, the resin layer 5 on the second principal surface Sf22 side is provided with the openings 9 at the positions corresponding respectively to the bump electrodes 2 of the semiconductor chip 1.

Then, the resin layer 5 shown in FIG. 2B is provided on the metal layers 8 shown in FIG. 2A, so that the external connection electrodes 11 are exposed as shown in FIG. 1C. The resin layer 5 shown in FIG. 2D is provided on the metal layers 8 shown in FIG. 2C, so that the external connection electrodes 11 are exposed as shown in FIG. 1D.

FIG. 3 shows an example of a case where the semiconductor device in FIG. 1 is mounted on a mounting board 30. The mounting board 30 is, for example, a printed board.

The mounting board 30 and the first principal surface Sf21 side of the external connection substrate 10 of the semiconductor device 100 are disposed to face each other. Then, the external connection electrodes 11 protruding from the semiconductor chip 1 are fixed to a conductive path 31 of the mounting board 30 by a conductive adhesive 32. The conductive adhesive 32 is, for example, solder.

The solder 32, being held up by surface tension, is welded to, and thus covers, the first principal surface Sf21 side, the side surfaces, and the second principal surface Sf22 side, of the metal layers 8 protruding from the semiconductor chip 1 (This welding is also hereinafter referred to as “protrusion welding”).

In other words, the solder 32 covers the first principal surface Sf21 side, the side surface, and the second principal surface Sf22 side of each external connection electrode 11. Thus, the external connection electrode 11 is connected to the conductive path 31 of the mounting board 30. Such protrusion welding with solder can be performed not only on the first principal surface Sf21 side, but also on the side surface and, on the second principal surface Sf22 side. For this reason, it is possible to improve the adhesive strength between the semiconductor device 100 and the mounting board 30, as compared with the structure in which, for example, only the first principal surface Sf21 side is fixed by using solder.

In this embodiment, provided is the external connection substrate 10 (or the external connection electrodes 11) protruding by, for example, approximately from 0.05 mm to 0.3 mm, from the semiconductor chip 1. This makes it possible to perform such protrusion welding. Moreover, the provision of the cutouts 7 at the edge portions of the external connection substrate 10 allows solder to easily flow around to the second principal surface Sf22 side, along the shapes of the cutouts 7, thus improving the adhesion.

In this way, the semiconductor chip 1 is flip-chip mounted on the mounting board 30 with the external connection substrate 10 in between. The bump electrodes 2 are thus connected to the conductive path 31 of the mounting board 30 with the external connection electrodes 11 in between.

In addition, the solder resist used for the resin layer 5 functions to restrict the flow of solder, in turn preventing a short circuit from occurring between the external connection electrodes 11.

As described above, according to this embodiment, the welding of the solder to the external connection electrodes 11 protruding from the semiconductor chip 1 improves the bonding strength between the semiconductor chip 1 and the mounting board 30. Moreover, the insulating adhesive 3 filled between the semiconductor chip 1 and the external connection substrate 10 improves the bonding strength between the bump electrodes 2 and the external connection electrodes 11.

Accordingly, even in a structure in which chip shrink is achieved by reducing the bump diameter of the bump electrodes 2, reliability can be improved. Specifically, even when, for example, a shock is applied from the outside to the structure, it is possible to prevent a poor connection from occurring due to peeling off of the semiconductor chip from the mounting board.

Since the adhesive strength is improved, the bump diameter, which has conventionally been 300 μm, can be reduced to 80 μm, for example. As a result, a further reduction in chip size, which has been conventionally limited due to the bump diameter and the clearance of the bumps, can be achieved.

When the bump diameter is large as in the conventional case, there is a problem that the chip size cannot be shrunk while the size of the element region, where a transistor cell is disposed, can be reduced by the progress of finer processes. However, according to this embodiment, even in a structure having a smaller chip size with a reduced bump diameter, the peeling off of the semiconductor chip from the mounting board can be prevented. For example, when the chip characteristics are maintained at the same level as those of the conventional chips, the chip size can be reduced by approximately 10%. As a result, the wafer yield is improved.

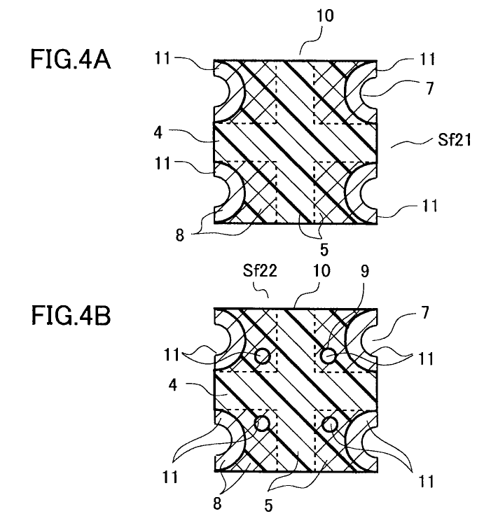

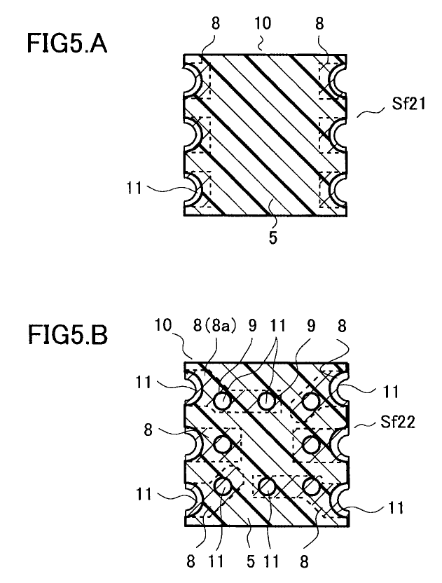

FIGS.4A and 4B as well as FIGS. 5A and 5B show other patterns of the external connection substrate 10.

FIGS. 4A and 4B show a case where the external connection electrodes 11 are disposed on two sides, opposite to each other, of the external connection substrate 10. FIG. 4A is a plan view showing the first principal surface Sf21 side. FIG. 4B is a plan view showing the second principal surface Sf22 side. In this manner, the external connection electrodes 11 may be provided on the sides of the external connection substrate 10, in accordance with the pattern of the conductive path on the mounting board side.

The cutouts 7 are provided, in a semicircle shape, on the two sides, opposite to each other, of the insulating film 4. The metal layers 8 are provided at, for example, the corner portions of the insulating film 4, so as to cover the first principal surface Sf21, the second principal surface Sf22, and the side surfaces of the edge portions.

The resin layers 5 are patterned so that each metal layer 8 is exposed in a band shape along the semicircle shape of the corresponding cutout 7. The external connection substrate 10 having the external connection electrodes 11 provided on the two sides, opposite to each other, is thus formed.

FIGS. 5A and 5B show a case where a larger number of the external connection electrodes 11 are provided. FIG. 5A is a plan view showing the first principal surface Sf21 side, and FIG. 5B is a plan view showing the second principal surface Sf22 side. Note that, here, shown is a case where the external connection electrodes 11 are provided on two sides, opposite to each other, of the external connection substrate 10. However, the external connection electrodes 11 may be provided additionally on the other two sides.

Moreover, in this case, the pattern of the metal layers 8 is different between the first principal surface Sf21 side and the second principal surface Sf22 side. The disposition and clearance (pitch) of the bump electrodes 2 of the semiconductor chip 1 sometimes do not coincide with the disposition and clearance (pitch) of the conductive path of the mounting board. However, according to this embodiment, provided is the external connection substrate 10 in which a desired pattern of the external connection electrodes 11 is formed. As a result, even when the layout of the bump electrodes of the semiconductor chip is different from that of the conductive path of the mounting board (particularly when the semiconductor chip is small), the mounting can be performed without changing these layouts.

When the semiconductor chip to be mounted is small, the pattern of each metal layer 8 on the second principal surface Sf22 side is extended in a direction toward the center so as to correspond to the position of the bump electrode of the semiconductor chip, and concurrently, the openings 9 are provided in the resin layer 5, as indicated by FIG. 5B.

In addition, providing two openings 9 for one metal layer 8 (for example, a metal layer 8a) allows two bump electrodes at the same potential to be led from one external connection electrode 11.

Moreover, the pattern of the external connection electrodes 11 exposed to the first principal surface Sf21 side is not limited to that shown in FIG. 5A, and a desired pattern may be employed therefor. For example, in FIG. 5B, each metal layer 8 is extended to a vicinity of the center of the external connection substrate 10. Moreover, openings are formed in the resin layer 5 with a desired pattern. As a result, a connection with the conductive path of the mounting board can be established even in the vicinity of the center of the external connection substrate 10. It should be noted that, even in such a case, each metal layer 8 (the external connection electrode 11) on the first principal surface Sf21 side and the corresponding metal layer 8 on the second principal surface Sf22 side are connected to each other at the portion of the cutout 7.

In this way, the external connection electrodes 11 provided on the insulating film 4 (particularly on the second principal surface Sf22 side thereof) may be formed freely in a desired pattern. Furthermore, since the openings 9 corresponding to the bump electrodes 2 are provided at desired positions in the resin layer 5, the present invention may be employed with versatility to correspond to the layout of terminals on the mounting board side (for example, to the distance between terminals).

For example, suppose a case where a chip size is reduced when the distance between terminals on the mounting board side is set to a predetermined value in accordance with the specifications. In such a case, the distance between the bump electrodes 2 on the chip does sometimes not coincide with the distance between the terminals on the mounting board side. In other words, even if the chip size can be shrunk by the progress of finer processes, when the chip size is determined in accordance with the layout on the mounting board side, the wafer yield is reduced.

However, in this embodiment, even the semiconductor chip 1 having a shrunk chip size can be mounted without, for example, changing the layout of the semiconductor chip 1 or the mounting board.

The description has been given so far by giving the examples in each of which one element region 20 is provided to one semiconductor chip 1. However, multiple element regions 20 may be provided on one chip.

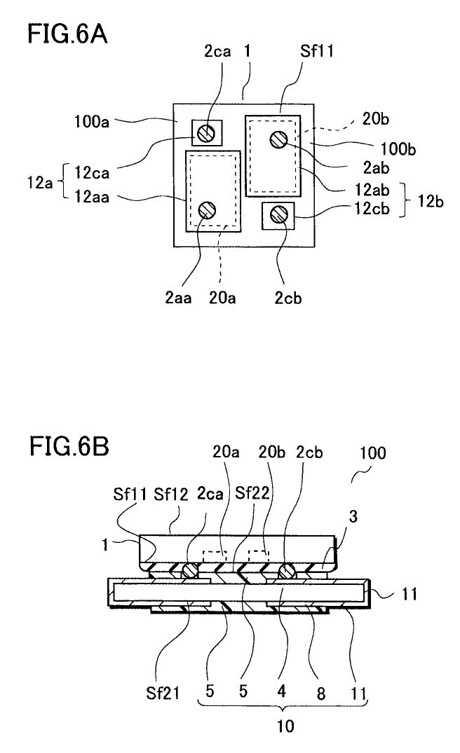

FIGS. 6A and 6B show an example of the semiconductor device 100 having multiple element regions. FIG. 6A is a plan view showing the first principal surface Sf21 side of the semiconductor chip 1. FIG. 6B is a cross-sectional view showing the semiconductor device 100, and corresponding to that of FIG. 1B.

An element region 20a (indicated by the broken line) for a first MOSFET 100a and an element region 20b (indicated by the broken line) for a second MOSFET 100b are integrated in the single semiconductor chip 1 where these first and second MOSFET 100a and 100b share the same drain region. In other words, two separated channel regions are provided in a continuous semiconductor substrate serving as a drain region, and a large number of MOSFET cells are disposed in each channel region.

Wiring electrode layers 12a and 12b are provided on the first principal surface Sf11 side of the semiconductor chip 1. The wiring electrode layer 12a constitutes a source electrode 12aa and a gate pad electrode 12ca which are connected to a source region and a gate electrode of the element region 20a, respectively. The wiring electrode layer 12b constitutes a source electrode 12ab and a gate pad electrode 12cb which are connected to a source region and a gate electrode of the element region 20b, respectively.

Moreover, a source bump electrode 2aa, a source bump electrode 2ab, a gate bump electrode 2ca, and a gate bump electrode 2cb are disposed in the semiconductor chip 1. The source bump electrode 2aa and the gate bump electrode 2ca are connected to the element region 20a. The source bump electrode 2ab and the gate bump electrode 2cb are connected to the element region 20b.

The external connection substrate 10 having the external connection electrodes 11 connected to these electrodes is provided on the first principal surface Sf11 side of the semiconductor chip 1, as shown in FIG. 6B. The external connection electrodes 11 are connected to the source bump electrodes 2aa and 2ab as well as the gate bump electrodes 2ca and 2cb.

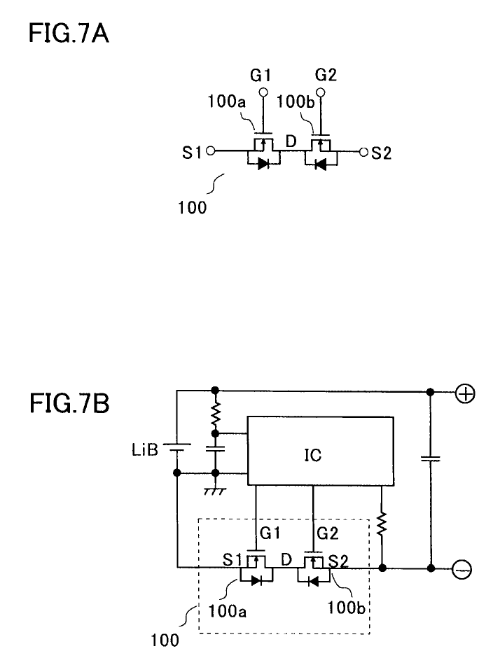

FIGS. 7A and 7B are circuit diagrams showing the semiconductor device 100 in FIG. 6A. FIG. 7A is an equivalent circuit diagram of the semiconductor chip 1. FIG. 7B shows an example of a circuit diagram illustrating a protection circuit for a secondary battery employing the semiconductor device 100.

The first MOSFET 100a and the second MOSFET 100b share a common drain D connected thereto, while each having its own source S1 or S2 and gate G1 or G2, as terminals led to the outside, as shown in FIG. 7A. The semiconductor device 100 switches current paths in accordance with control signals applied to the gate G1 of the first MOSFET 100a and the gate G2 of the second MOSFET 100b, and concurrently in accordance with the potential difference between the two sources S1 and S2

Such a semiconductor device 100 is preferably employed for a protection circuit for a secondary battery, as shown in FIG. 7B.

Specifically, the semiconductor device 100 is connected in series to a secondary battery LiB. In the semiconductor device 100, the first MOSFET 100a and the second MOSFET 100b share the common drain D connected thereto. The source S1 of the first MOSFETs 100a and the source S2 of the second MOSFET 100b are arranged respectively at the two ends of the semiconductor device 100.

In addition, the gates Gi and G2 of the first and second MOSFETs 100a and 100b are connected to a control circuit IC. The control circuit IC performs on-off control of the first MOSFET 100a and the second MOSFET 100b, while detecting the voltage of the secondary battery LiB. The control circuit IC thus protects the secondary battery LiB from overcharge, overdischarge, and load short-circuiting.

For example, the control circuit IC detects the battery voltage. When the detected voltage is higher than a set maximum voltage, the control circuit IC turns off the second MOSFET 100b to prevent the overcharge of the secondary battery LiB with a current path formed by the first MOSFET 100a and a parasitic diode of the second MOSFET 100b. On the other hand, when the detected voltage is lower than a set minimum voltage, the control circuit IC turns off the first MOSFET 100a to prevent the overdischarge of the secondary battery LiB with a current path formed by the second MOSFET 100b and a parasitic diode of the first MOSFET 100a.

The chip size of such a semiconductor device 100 having two element regions 20a and 20b as described above becomes relatively large. However, since there is no need to lead the drain to the outside, the size of the device is often reduced as much as possible by performing flip-chip mounting.

In this embodiment, by using the small bump electrodes 2 and the external connection electrodes 11 (the external connection substrate 10), the matching with the pattern layout on the mounting board side is improved. Concurrently, the peeling off of the semiconductor chip from the mounting board can be prevented.

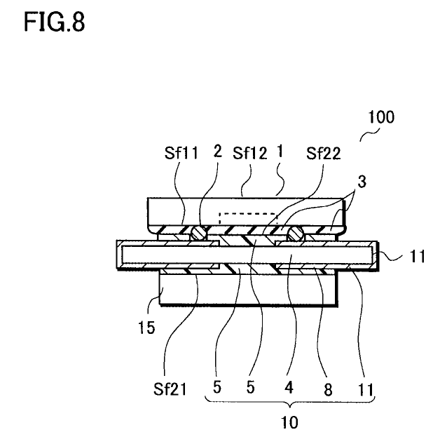

FIG. 8 is a cross-sectional view showing a second embodiment. In the second embodiment, an external connection substrate 10 is provided with a reinforcement member 15 on the first principal surface Sf21 side of the external connection substrate 10.

A base material of the external connection substrate 10 is an insulating film 4 made of polyimide or the like, as described above. Therefore, when the strength of the final structure of the semiconductor device 100 is insufficient, it is preferable that a sheet of polyimide or the like having a thickness of approximately 0.3 mm be provided as the reinforcement member 15 on the first principal surface Sf21 side.

According to the embodiments, the following effects can be achieved. Firstly, even when the bump diameter of a bump electrode is reduced, a favorable adhesion between a semiconductor chip and a mounting board can be obtained. Specifically, the edge portions of an insulating film larger than the semiconductor chip are covered with the external connection electrodes, while the film is bonded to the chip. Accordingly, the external connection electrodes protruding from the edge portions of the chip can be obtained. The external connection electrodes and the bump electrodes can be bonded together with a sufficient strength by the insulating adhesive filled between the film and the chip. With this structure, at the time of mounting, the protrusion welding with solder can be performed on the surfaces of the protruding external connection electrodes. As a result, the bonding strength between the mounting board and the semiconductor chip can be improved.

Accordingly, even in a structure in which chip shrink is achieved by reducing the bump diameter of the bump electrodes, the reliability can be improved. Specifically, even when, for example, a shock from the outside is applied, the peeling off of the semiconductor chip from the mounting board can be prevented.

Secondly, cost reduction can be achieved by reducing the size of the chip. There has been a problem that when the bump diameter is large as in the conventional case, although the element region where a transistor cell is disposed can be made smaller by the progress of finer processes, the chip size cannot be shrunk. However, according to the embodiments, even in a structure having a chip size made smaller by reducing the bump diameter, the peeling off of the semiconductor chip from the mounting board can be prevented. For example, when the chip characteristics are maintained at the same level as those of the conventional chips, the chip size can be reduced by approximately 10%. As a result, the wafer yield is improved.

Thirdly, the external connection electrode provided on the insulating film may be formed freely in a desired pattern. Furthermore, since a contact hole corresponding to the bump electrode can be provided at a desired position in the resin layer covering the film and parts of the external connection electrodes, the present invention may be employed with versatility to correspond to the layout of terminals on the mounting board side(for example, to the distance between terminals). For example, suppose a case where a chip size is reduced when the distance between terminals on the mounting board side is set to a predetermined value in accordance with the specifications. In such a case, the distance between the bump electrodes on the chip is sometimes different from the distance between the terminals on the mounting board side. However, according to the embodiments, the external connection electrode is provided on both of the principal surfaces of the insulating film. On one principal surface side, the bump electrode and the external connection electrode are connected to each other, while on the other principal surface side, the external connection electrode and the terminal of the mounting board side are connected to each other. Thus, even in a small chip size, the semiconductor device matching the layout of the mounting board can be provided.

What is claimed is:

1. A semiconductor device comprising:
a semiconductor chip comprising a device element formed therein and a bump electrode disposed on a surface of the semiconductor chip; and
an external connection substrate adhered to the surface of the semiconductor chip by an insulating adhesive, a lateral size of the external connection substrate being larger than a lateral size of the semiconductor chip so that an edge portion of the external connection substrate is not covered by the semiconductor chip; and
an external connection electrode disposed on the external connection substrate so as to cover the edge portion of external connection substrate and connected to the bump electrode.

2. The semiconductor device of claim 1, further comprising a first resin layer disposed on a surface of the external connection substrate on which the insulating adhesive is applied and a second resin layer disposed on another surface of the external connection substrate opposite from said surface of the external connection substrate.

3. The semiconductor device of claim 2, wherein the external connection electrode covers the surface and the another surface of the external connection substrate as well as a side surface of the external connection substrate.

4. The semiconductor device of claim 2, wherein a cutout is formed in the external connection substrate at an edge thereof.

5. The semiconductor device of claim 1, wherein the device element comprises an insulated gate semiconductor element.

6. The semiconductor device of claim 1, further comprising a reinforcement member disposed on a surface of the external connection substrate opposite from a surface of the external connection substrate on which the insulating adhesive is applied

7. The semiconductor device of claim 1, wherein the bump electrode comprises gold, copper, a gold-tin alloy or a solder.

8. The semiconductor device of claim 5, wherein the insulated gate semiconductor element comprises two element regions and two corresponding drain regions, wherein the drain regions are connected in a surface of the semiconductor chip opposite from the surface of the semiconductor chip on which the bump electrode is disposed.

9. The semiconductor device of claim 1, further comprising a mounting board comprising a conductive path, wherein the external connection electrode covering the edge portion of external connection substrate is in contact with a conductive adhesive which adheres the external connection substrate and the mounting board together.
